(19) United States
(12) Patent Application Publication
(10) Pub. No.: US 2021/0075387 A1
(43) Pub. Date: Mar. 11, 2021

(54) LIMITING AMPLIFIER CIRCUITRY

(71) Applicant: Mitsubishi Electric Corporation, Tokyo (JP)

(72) Inventors: Takanori KAWANAKA, Tokyo (JP); Yusuke MITSUI, Tokyo (JP)

(73) Assignee: Mitsubishi Electric Corporation, Tokyo (JP)

(21) Appl. No.: 17/100,442

(22) Filed: Nov. 20, 2020

Related U.S. Application Data
(63) Continuation of application No. PCT/JP2018/025514, filed on Jul. 5, 2018.

(51) Int. Cl. H03F 3/45; H03F 1/02

(52) U.S. Cl. CPC H03F 3/45475; H03F 2200/375; H03F 1/02

(57) ABSTRACT

A limiting amplifier circuitry according to the disclosure includes: a first differential amplifier circuitry capable of adjusting, as voltage offset, a difference between direct-current voltage components of first differential signals input thereto, the first differential amplifier circuitry amplifying the first differential signals and outputting the amplified first differential signals as second differential signals; a second differential amplifier circuitry that amplifies the second differential signals with an amplification factor depending on a difference between direct-current voltage components of the second differential signals; a signal detecting circuitry that detects an amplitude of the second differential signals, determines whether or not the amplitude is larger than a threshold, and outputs a determination result; and an offset control circuitry that controls the voltage offset by using the determination result.

### CROSS-REFERENCE TO RELATED APPLICATION

This application is a continuation application of International Application PCT/JP2018/025514, filed on Jul. 5, 2018, and designating the U.S., the entire contents of which are incorporated herein by reference.

### BACKGROUND OF THE INVENTION

### 1. Field of the Invention

The disclosure relate to a limiting amplifier circuitry.

### 2. Description of the Related Art

In recent years, point-to-multipoint access optical communication systems called passive optical network (PON) systems that allow one optical fiber to be shared by a plurality of users have been widely used. A PON system includes: one optical line terminal (OLT), which is a station side device; a plurality of optical network units (ONUs), which are subscriber side terminal devices; optical star couplers, which are passive elements connecting the OLT and the ONUs with one another; and optical fibers that connect the OLT, the ONUs, and the optical star couplers.

In order to increase the capacity of the PON systems, there have been demands for extension of a maximum connection distance between an OLT and an ONU or increase in the number of branches of ONUs. Thus, the distances between an OLT and ONUs are not constant, and the OLT has to receive packet signals with large signal strength differences. Typically, an optical signal transmitted via an optical fiber is converted from the optical signal into a current signal by a photoelectric conversion element called a photodetector. The current signal obtained by the conversion is amplified by a pre-amplifier, called a transimpedance amplifier, having a high gain. The output amplitude of the pre-amplifier is dependent on an input light power. Signals output from the pre-amplifier are limited to a constant voltage amplitude by a circuitry called a limiting amplifier circuitry. Generation of signals with a constant voltage amplitude independent of the input light power is an essential process for a stable signal identification by a clock data recovery circuitry subsequent to the limiting amplifier circuitry. In the meantime, noise output from the pre-amplifier during no-signal periods is amplified by a high gain by the limiting amplifier circuitry and then input to the clock data recovery circuitry. Thus, the clock data recovery circuitry may provide false detection due to the amplified noise.

A limiting amplifier circuitry taught in Japanese Patent No. 4956639 includes a squelch circuitry that fixes the voltage output from the limiting amplifier circuitry to a constant value during no-signal periods in order to avoid false detection at the clock data recovery circuitry due to amplified noise.

The limiting amplifier circuitry described in Japanese Patent No. 4956639, however, has a problem in that power consumption is increased because the squelch circuitry is additionally provided subsequent to a main amplifier stage.

The disclosure has been made in view of the above, and an object thereof is to provide a limiting amplifier circuitry having a squelch function while suppressing increase in power consumption.

### SUMMARY OF THE INVENTION

To solve the above problem and achieve the object, a limiting amplifier circuitry according to the disclosure includes: a first differential amplifier circuitry capable of adjusting, as voltage offset, a difference between direct-current voltage components of first differential signals input thereto, the first differential amplifier circuitry amplifying the first differential signals and outputting the amplified first differential signals as second differential signals; a second differential amplifier circuitry to amplify the second differential signals with an amplification factor depending on a difference between direct-current voltage components of the second differential signals; a signal detecting circuitry to detect an amplitude of the second differential signals, determine whether or not the amplitude is larger than a threshold, and output a determination result; and an offset control circuitry to control the voltage offset by using the determination result.

### BRIEF DESCRIPTION OF THE DRAWINGS

FIG. 1 is a diagram illustrating a configuration of a limiting amplifier circuitry according to a first embodiment;

FIG. 2 is a diagram illustrating an example of a control circuitry included in the limiting amplifier circuitry according to the first embodiment;

FIG. 3 is a graph illustrating input-output characteristics of a first differential amplifier circuitry in a case where a result of determination in the limiting amplifier circuitry according to the first embodiment is a first value;

FIG. 4 is a graph illustrating input-output characteristics of a second differential amplifier circuitry in the case where a result of determination in the limiting amplifier circuitry according to the first embodiment is the first value;

FIG. 5 is a graph illustrating input-output characteristics of the first differential amplifier circuitry in a case where a result of determination in the limiting amplifier circuitry according to the first embodiment is a second value;

FIG. 6 is a graph illustrating input-output characteristics of the second differential amplifier circuitry in the case where a result of determination in the limiting amplifier circuitry according to the first embodiment is the second value;

FIG. 7 is a diagram illustrating a configuration of a limiting amplifier circuitry according to a second embodiment; and

FIG. 8 is a diagram illustrating a configuration of a limiting amplifier circuitry according to a third embodiment.

### DETAILED DESCRIPTION OF THE PREFERRED EMBODIMENTS

A limiting amplifier circuitry according to certain embodiments of the disclosure will be described in detail below with reference to the drawings.

### First Embodiment

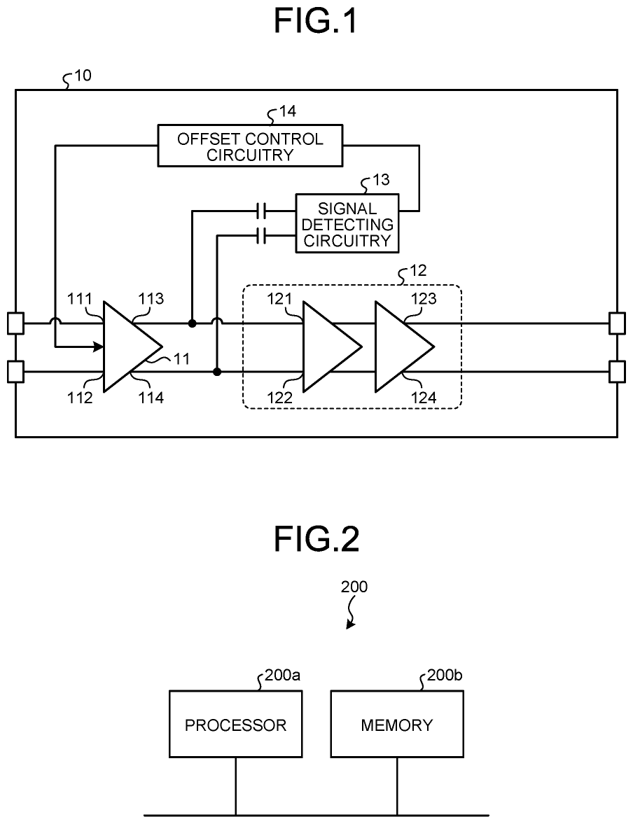

FIG. 1 is a diagram illustrating a configuration of a limiting amplifier circuitry according to a first embodiment. A limiting amplifier circuitry 10 includes a first differential amplifier circuitry 11, a second differential amplifier circuitry 12, a signal detecting circuitry 13, and an offset control circuitry 14.

The first differential amplifier circuitry 11 includes a signal input terminal 111, a signal input terminal 112, a signal output terminal 113, and a signal output terminal 114. An input signal Vin1 is input to the signal input terminal 111. An input signal Vin2 is input to the signal input terminal 112. The input signal Vin1 and the input signal Vin2 are also referred to as first differential signals. The signal output terminal 113 amplifies the input signal Vin1 and outputs an output signal Vout1. The signal output terminal 114 amplifies the input signal Vin2 and outputs an output signal Vout2. The output signal Vout1 and the output signal Vout2 are also referred to as second differential signals. In addition, the first differential amplifier circuitry 11 adjusts a difference between direct-current (DC) voltage components of the first differential signals as voltage offset. The second differential amplifier circuitry 12 includes a signal input terminal 121, a signal input terminal 122, a signal output terminal 123, and a signal output terminal 124. An input signal Vin3 is input to the signal input terminal 121. An input signal Vin4 is input to the signal input terminal 122. The signal output terminal 123 outputs an output signal Vout3. The signal output terminal 124 outputs an output signal Vout4. In addition, the second differential amplifier circuitry 12 amplifies the second differential signals by an amplification factor depending on the difference between DC voltage components of the second differential signals. The signal detecting circuitry 13: detects the amplitude of the second differential signals; determines whether or not the amplitude is larger than a threshold; determines that a signal is detected when the amplitude of the second differential signal larger than the threshold is detected; and outputs the determination result to the offset control circuitry 14. In addition, the signal detecting circuitry 13 determines that no signal is detected when the amplitude of the second differential signals equal to or smaller than the threshold is detected, and outputs the determination result to the offset control circuitry 14. The offset control circuitry 14 controls the voltage offset of the first differential amplifier circuitry 11 on the basis of the determination results from the signal detecting circuitry 13. In addition, the offset control circuitry 14 is designed as a digital circuitry with a very small static power consumption. The offset control circuitry 14 thus consumes less power than a typical squelch circuitry.

The signal detecting circuitry 13 and the offset control circuitry 14 according to the embodiment are implemented by processing circuitry that is electronic circuitry for carrying out respective processes.

The processing circuitry may be dedicated hardware, or may be a control circuitry including a memory and a central processing unit (CPU) that executes programs stored in the memory. Note that the memory is a nonvolatile or volatile semiconductor memory such as a random access memory (RAM), a read only memory (ROM) or a flash memory, a magnetic disk, or an optical disk, for example. In a case where the processing circuitry is a control circuitry including a CPU, the control circuitry is a control circuitry 200 having a configuration illustrated in FIG. 2, for example.

As illustrated in FIG. 2, the control circuitry 200 includes a processor 200a, which is a CPU, and a memory 200b. In a case of implementation by the control circuitry 200 illustrated in FIG. 2, the processor 200a reads and executes programs, which correspond to the respective processes, stored in the memory 200b. Furthermore, the memory 200b is also used as a temporary memory in processes performed by the processor 200a.

The operation of the limiting amplifier circuitry 10 will be explained. First differential signals input to the limiting amplifier circuitry 10 are amplified by the first differential amplifier circuitry 11. The signal detecting circuitry 13 extracts the amplitude of the signals amplified by the first differential amplifier circuitry 11, and compares the amplitude of the signals with the threshold. If the amplitude of a signal is larger than the threshold as a result of the comparison, the signal detecting circuitry 13 determines that a signal is detected, and outputs a first value as a determination result. In contrast, if the amplitude of a signal is equal to or smaller than the threshold as a result of the comparison, the signal detecting circuitry 13 determines that no signal is detected, and outputs a second value as a determination result. The signal detecting circuitry 13 transmits the determination results to the offset control circuitry 14. The offset control circuitry 14, in receipt of the determination results from the signal detecting circuitry 13, controls the voltage offset between the second differential signals at the first differential amplifier circuitry 11. The outputs of the first differential amplifier circuitry 11 are amplified by the second differential amplifier circuitry 12 so that the signals with amplitudes ranging from a small value to a large value are output with a constant amplitude. Next, the operation of the limiting amplifier circuitry 10 will be explained in detail separately for a case where the determination result of the signal detecting circuit 13 is the first value and for a case where the determination result is the second value.

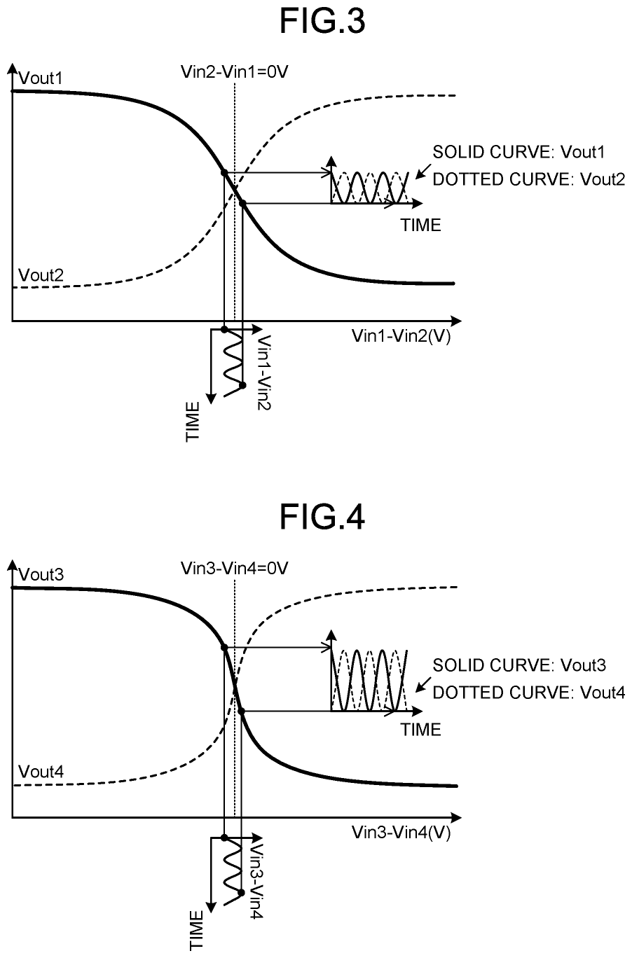

The case where the determination result of the signal detecting circuitry 13 is the first value will now be explained. FIG. 3 is a graph illustrating input-output characteristics of the first differential amplifier circuitry 11 in the case where the result of determination in the limiting amplifier circuitry 10 according to the first embodiment of the disclosure is the first value. The horizontal axis illustrated in FIG. 3 represents an input terminal voltage difference that is a value obtained by subtracting the input signal Vin2 from the input signal Vin1. The vertical axis illustrated in FIG. 3 represents the voltage of the output signal Vout1 or the output signal Vout2. In FIG. 3, a solid curve represents the characteristics of the input terminal voltage difference and the output signal Vout1, and a dotted curve represents the characteristics of the input terminal voltage difference and the output signal Vout2. In the case where the determination result of the signal detecting circuitry 13 is the first value, the first differential amplifier circuitry 11 is caused to operate by the offset control circuitry 14 in a state in which the difference between the input signal Vin2 and the input signal Vin1 is 0 as illustrated in FIG. 3. FIG. 4 is a graph illustrating input-output characteristics of the second differential amplifier circuitry 12 in the case where the result of determination in the limiting amplifier circuitry 10 according to the first embodiment of the disclosure is the first value. The second differential amplifier circuitry 12 operates in the state in which the difference between the input signal Vin3 and the input signal Vin4 is 0 in a manner similar to the first differential amplifier circuitry 11. Note that the amount of change in output voltage with respect to input voltage, that is, a multiplication factor is sufficiently large relative to the operation as the limiting amplifier circuitry 10.

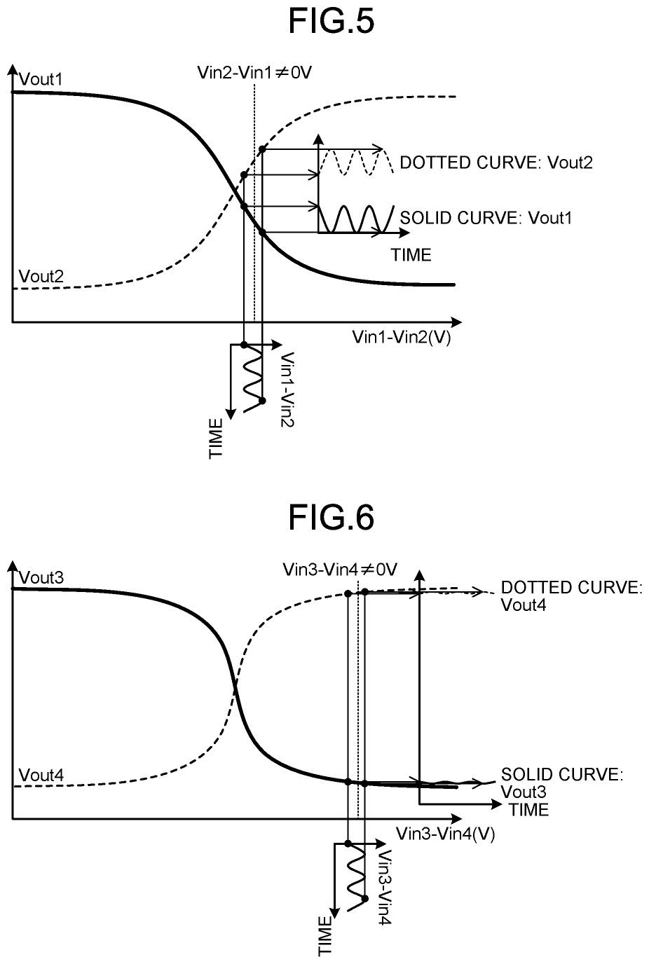

The case where the determination result of the signal detecting circuitry 13 is the second value will now be explained. FIG. 5 is a graph illustrating input-output characteristics of the first differential amplifier circuitry 11 in the case where the result of determination in the limiting amplifier circuitry 10 according to the first embodiment of the disclosure is the second value. What are represented by the horizontal axis, the vertical axis, the solid curve, and the dotted curve illustrated in FIG. 5 are similar to those in FIG. 3. The first differential amplifier circuitry 11 is adjusted by the offset control circuitry 14 to operate in a state in which a DC voltage difference is present between the input signal Vin1 and the input signal Vin2.

FIG. 6 is a graph illustrating input-output characteristics of the second differential amplifier circuitry 12 in the case where the result of determination in the limiting amplifier circuitry 10 according to the first embodiment of the disclosure is the second value. Because of the DC voltage difference between the output terminals caused by the first differential amplifier circuitry 11, the second differential amplifier circuitry 12 operates in a state in which a DC voltage difference is present between the two input terminals.

The amplification factor of the first differential amplifier circuitry 11 differs little between the states in FIGS. 3 and 5, that is, between the case where the determination result is the first value and the case where the determination result is the second value. This is to make the amplification factor to the signal detecting circuitry 13 constant independently of the signal detection state, so as to stably detect signals. When the determination result is the second value, the second differential amplifier circuitry 12 is caused to operate in a range in which the amplification factor relative to an input with a small amplitude can be regarded as almost 0. Thus, the output from the second differential amplifier circuitry 12 when the determination result is the second value, that is, when the input amplitude is as small as that of noise can be regarded as being fixed to a constant DC level. In addition, when the amplification factor when the determination result of the second differential amplifier circuitry 12 is the first value is referred to as a first amplification factor and the amplification factor when the determination result of the second differential amplifier circuitry 12 is the second value is referred to as a second amplification factor, it can be said that, when the determination result is the first value, the second differential amplifier circuitry 12 is configured to have the second amplification factor larger than the first amplification factor. In other words, it can be said that the amplification factor of the second differential amplifier circuitry when the determination result is the second value is smaller than the amplification factor of the second differential amplifier circuitry 12 when the determination result is the first value.

As described above, the method of adjusting the voltage offset of the first differential amplifier circuitry 11 enables the squelch function to be achieved without provision of a squelch circuitry in the limiting amplifier circuitry 10. In addition, although the limiting amplifier circuitry 10 needs to include the offset control circuitry 14, the offset control circuitry 14 can be designed as a digital circuitry with a very small static power consumption, which does not undermine the intended purpose of suppressing increase in power consumption. While a case where the DC voltage difference between input terminals of the first differential amplifier circuitry 11, that is, between the first differential signals is adjusted has been described in the first embodiment, a DC voltage difference between the output terminals of the first differential amplifier circuitry 11, that is, between the second differential signals may alternatively be adjusted. In addition, the limiting amplifier circuitry 10 may be an amplifier capable of changing a transmission band of a filter depending on an external rate selection signal. In the case of an amplifier capable of changing a transmission band of a filter, circuitry adjustment such as switching of the threshold for signal detection to enable the change of the bandwidth is also included as a component. Note that the filter includes a high-pass filter and a low-pass filter, and is included in the limiting amplifier circuitry 10.

### Second Embodiment

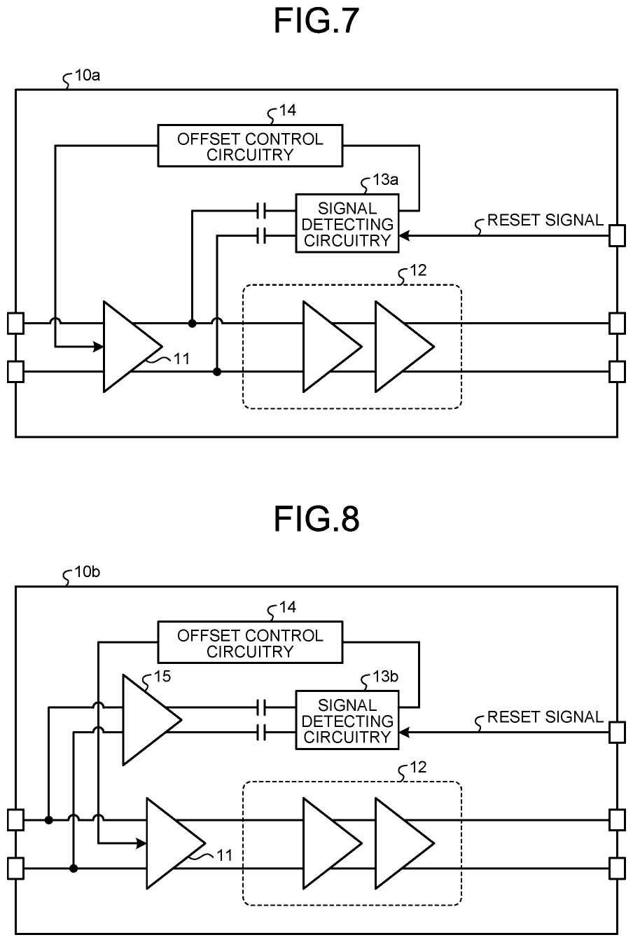

FIG. 7 is a diagram illustrating a configuration of a limiting amplifier circuitry according to a second embodiment of the disclosure. Note that components that have the same functions as those in the first embodiment will be represented by the same reference numerals as those in the first embodiment, and redundant description thereof will not be repeated. A limiting amplifier circuitry 10a is different from the limiting amplifier circuitry 10 in including a signal detecting circuitry 13a instead of the signal detecting circuitry 13. For high-speed switching operation of the signal detecting circuitry 13a, the signal detecting circuitry 13a receives a reset signal from outside of the limiting amplifier circuitry 10a. The signal detecting circuitry 13a resets the determination result in response to the reset signal, and immediately proceeds to an operation of detecting a signal after resetting in response to the reset signal. Note that resetting refers to forcing the determination result to be the first value or forcing the determination result to be the second value.

As described above, in the second embodiment, the limiting amplifier circuitry 10a can have a squelch function while suppressing increase in power consumption. In addition, the limiting amplifier circuitry 10a can perform the switching operation at high speed by using the reset signal.

### Third Embodiment

FIG. 8 is a diagram illustrating a configuration of a limiting amplifier circuitry according to a third embodiment of the disclosure. Note that components that have the same functions as those in the first embodiment will be represented by the same reference numerals as those in the first embodiment, and redundant description thereof will not be repeated. A limiting amplifier circuitry 10b includes a signal detecting circuitry 13b instead of the signal detecting circuitry 13. The limiting amplifier circuitry 10b also includes a third differential amplifier circuitry 15. The third differential amplifier circuitry 15 adjusts a voltage difference between the first differential signals as voltage offset so that the signal detecting circuitry 13b can stably detect a signal. That is, the third differential amplifier circuitry 15 for detecting first differential signals is provided separately from a main signal amplifier stage. While a configuration in which the reset signal is input to the signal detecting circuitry 13b is illustrated in FIG. 8 in a manner similar to FIG. 7, the reset signal need not be received by the signal detecting circuitry 13b.

As described above, in the third embodiment, the limiting amplifier circuitry 10b can have a squelch function while suppressing increase in power consumption. In addition, the limiting amplifier circuitry 10b includes the third differential amplifier circuitry 15, which enables the signal detecting circuitry 13b to stably detect a signal.

A limiting amplifier circuitry according to the disclosure produces an effect of being capable of having a squelch function while suppressing increase in power consumption.

The configurations presented in the embodiments above are examples of the disclosure, and can be combined with other known technologies or can be partly omitted or modified without departing from the scope of the disclosure.

What is claimed is:

1. A limiting amplifier circuitry comprising:
a first differential amplifier circuitry capable of adjusting, as voltage offset, a difference between direct-current voltage components of first differential signals input thereto, the first differential amplifier circuitry amplifying the first differential signals and outputting the amplified first differential signals as second differential signals;
a second differential amplifier circuitry to amplify the second differential signals with an amplification factor depending on a difference between direct-current voltage components of the second differential signals;
a signal detecting circuitry to detect an amplitude of the second differential signals, determine whether or not the amplitude is larger than a threshold, and output a determination result; and
an offset control circuitry to control the voltage offset by using the determination result.

2. The limiting amplifier circuitry according to claim 1, wherein
when the amplitude is larger than the threshold, the signal detecting circuitry outputs, as the determination result, a first value indicating that a signal is detected, and when the amplitude is equal to or smaller than the threshold, the signal detecting circuitry outputs, as the determination result, a second value indicating that no signal is detected.

3. The limiting amplifier circuitry according to claim 2, wherein an amplification factor of the second differential amplifier circuitry when the determination result is the second value is smaller than an amplification factor of the second differential amplifier circuitry when the determination result is the first value.

4. The limiting amplifier circuitry according to claim 1, wherein
upon receiving a signal for resetting the determination result, the signal detecting circuitry resets the determination result.

5. The limiting amplifier circuitry according to claim 1, comprising a third differential amplifier circuitry to detect the amplitude, disposed at an upstream of the signal detecting circuitry.

6. The limiting amplifier circuitry according to claim 1, wherein the limiting amplifier circuitry is capable of switching a transmission band of a filter depending on an external rate selection signal.
